(19) United States
(12) Patent Application Publication
(10) Pub. No.: US 2018/0090908 A1
(43) Pub. Date: Mar. 29, 2018

(54) Arrangement Having a Substrate and a Semiconductor Laser

(71) Applicant: OSRAM Opto Semiconductors GmbH, Regensburg (DE)

(72) Inventors: Roland Enzmann, Regensburg (DE); Markus Arzberger, Sunnyvale, CA (US)

(21) Appl. No.: 15/565,188

(22) PCT Filed: Apr. 29, 2016
(86) PCT No.: PCT/EP2016/059674

§ 371 Date: Oct. 9, 2017

(30) Foreign Application Priority Data
Apr. 30, 2015 (DE) 10 2015 106 712.9

(51) Int. Cl. H01S 5/022; H01S 5/02

(52) U.S. Cl. CPC H01S 5/02256; H01S 5/02272; H01L 2224/48091; H01S 5/0206

(57) ABSTRACT

An arrangement having a substrate and a semiconductor laser and a method for manufacturing such an arrangement are disclosed. In an embodiment, the arrangement includes a substrate and a semiconductor laser, wherein the substrate has a top, side areas and a bottom, wherein at least one first recess is provided at the top, wherein the semiconductor laser is arranged on the top of the substrate such that a region of the side area of the semiconductor laser via which the electromagnetic radiation is emitted is arranged above the first recess.

This patent application is a national phase filing under section 371 of PCT/EP2016/059674, filed Apr. 29, 2016, which claims the priority of German patent application 10 2015 106 712.9, filed Apr. 30, 2015, each of which is incorporated herein by reference in its entirety.

### TECHNICAL FIELD

The present invention relates to an arrangement having a substrate and having a semiconductor laser according to patent claim 1, and a method for manufacturing the arrangement according to patent claim 11.

### BACKGROUND

In the prior art, it is known, for example, from EP 1 792 373 B1, to mount a semiconductor laser on a carrier. The manufacture is relatively complex.

### SUMMARY OF THE INVENTION

The object of the present invention is to provide an arrangement having a substrate and a laser, which can be manufactured in a simple and economical manner.

This object is achieved via claims 1 and 11.

Additional embodiments are provided in the dependent claims.

One advantage of the provided arrangement is that the electromagnetic radiation emitted by the semiconductor laser is influenced less by the substrate. This is achieved in that the region of the semiconductor laser which emits the electromagnetic radiation is arranged above a first recess in the substrate. The side face of the semiconductor laser in the region in which the electromagnetic radiation is emitted has a protrusion with respect to the upper side of the substrate. The substrate has the first recess, which is introduced into the upper side of the substrate. With the aid of the recess, more free space is available for the electromagnetic radiation.

Additional embodiments are provided in the dependent claims.

In one embodiment, the first recess is introduced bordering on a side face of the substrate, wherein the first recess is open laterally at the side face. Thus, increased free space is provided for emitting the electromagnetic radiation.

In an additional embodiment, a first contact pad is configured on the upper side of the substrate, wherein the first contact pad extends from the upper side at least into the first recess, and wherein a first electrical terminal of the semiconductor laser is connected to the first contact pad. In this way, increased flexibility is provided in connecting the first electrical contact of the semiconductor laser to a contact of a carrier. In addition, by means of the first contact pad, the electrical contacting of the semiconductor laser is possible in a simple and reliable manner.

In an additional embodiment, the first recess extends from the upper side of the substrate to the lower side of the substrate. In addition, the first contact pad is routed from the upper side of the substrate via the first recess to the lower side of the substrate. Thus, the first electrical terminal of the semiconductor laser may be electrically contacted via the lower side of the substrate. Simple mounting and contacting of the semiconductor laser is therefore possible via a carrier.

In an additional embodiment, at least a second recess is introduced into the upper side, wherein the second recess borders on a side face of the substrate and/or is routed from the upper side of the substrate to the lower side of the substrate. In addition, a second contact pad is configured on the upper side of the substrate, wherein the second contact pad extends from the upper side of the substrate at least into the second recess. In addition, a second electrical terminal of the semiconductor laser is connected to the second contact pad. Thus, simple and reliable electrical contacting of the second electrical terminal of the semiconductor laser is provided, wherein in addition, simple and reliable mounting and electrical contacting of the second electrical contact of the semiconductor laser is possible via corresponding mounting of the substrate via the side face or via the lower side.

In an additional embodiment, the second recess extends from the upper side of the substrate to the lower side of the substrate, and the second contact pad is routed from the upper side of the substrate via the second recess to the lower side of the substrate. Thus, simple electrical contacting of the second electrical terminal of the semiconductor laser may take place via the lower side of the substrate.

In an additional embodiment, at least a third recess is introduced into the upper side of the substrate, wherein the third recess borders on a side face of the substrate or is routed from the upper side of the substrate to the lower side of the substrate. In addition, a third contact pad is configured on the upper side of the substrate, wherein the third contact pad extends at least into the third recess, and wherein the third contact pad is connected to the second electrical terminal of the semiconductor laser. Thus, a reduction in the electrical impedance of the semiconductor laser is achieved.

In an additional embodiment, the substrate is mounted on a carrier via the side face on which the first recess is configured. In addition, the carrier includes an additional first electrical contact which is electrically conductively connected, in particular directly mechanically connected, to the first contact pad. Thus, simple mounting of the arrangement on a carrier is made possible, wherein simple and reliable electrical contact is simultaneously established between the carrier and the first electrical terminal of the semiconductor laser.

In an additional embodiment, the carrier has a second additional electrical contact, wherein the second contact pad of the substrate is electrically conductively connected, in particular directly mechanically connected, to the second additional electrical contact of the carrier. Thus, the second electrical terminal of the semiconductor laser is also electrically conductively connected to a second additional electrical contact of the carrier in a simple and reliable manner.

Depending on the chosen embodiment, the carrier has a third additional electrical contact, wherein the third contact pad of the substrate is electrically conductively connected, in particular directly mechanically connected, to the third additional electrical contact of the carrier. Thus, the third contact pad is also electrically and/or in particular mechanically connected to the third additional electrical contact of the carrier in a simple and reliable manner.

Depending on the chosen embodiment, the first, the second, and/or the third recess may be configured in the substrate in the form of a hole or in the form of a hole which is open laterally in the longitudinal direction. The configuration of a hole may be produced economically via simple means. The hole may be routed from the upper side to the lower side of the substrate.

The provided method has the advantage that the arrangement having the substrate and having the semiconductor laser may be manufactured in a simple manner. This is achieved in that a substrate plate is made available which has multiple recesses. In addition, multiple semiconductor lasers are mounted on the substrate plate in such a way that the semiconductor lasers are respectively arranged with a region of the side face which emits the electromagnetic radiation being above the first recess. Subsequently, the substrate plate is divided into substrates having at least one semiconductor laser. With the aid of the described method, the time for manufacturing a substrate having at least one semiconductor laser is shortened and simplified compared to individual mounting of a semiconductor laser on a substrate.

In an additional embodiment of the method, multiple first contact pads which are separate from one another are applied to the upper side of the substrate plate in such a manner that the first contact pads extend from the upper side of the substrate plate into an associated first recess. In addition, first electrical terminals of the semiconductor lasers are electrically conductively connected to one respective first contact pad, in particular, the semiconductor lasers are placed on first contact pads, and first electrical terminals of the semiconductor lasers are thereby mechanically and electrically connected directly to the first contact pads. Thus, simple and reliable electrical contacting of the semiconductor laser is provided.

In an additional embodiment of the method, the substrate is arranged on a carrier via the side face on which the first recess borders, or via the lower side. The carrier has a first additional electrical contact, wherein the first contact pad of the substrate is electrically conductively connected, in particular directly mechanically connected, to the first additional electrical contact of the carrier. Thus, simple and reliable mounting of the substrate on the carrier is achieved, wherein in addition, reliable electrical contacting is achieved between the first contact pad of the substrate and a first additional electrical contact pad of the carrier.

In an additional embodiment, the substrate plate is divided into the individual substrates with the aid of a breaking operation. Depending on the chosen embodiment, an intended fracture edge is introduced on a lower side of the substrate plate with the aid of a laser. Subsequently, the substrate plate is broken along the intended fracture edge. Thus, a simple and reliable method for dividing the substrate plate into individual substrates is provided.

### BRIEF DESCRIPTION OF THE DRAWINGS

The above-described properties, features, and advantages of this invention, as well as the manner in which it is achieved, will become clearer and more readily comprehensible in conjunction with the following description of the exemplary embodiments which are explained in conjunction with the drawings, wherein

FIG. 1 shows a section of a substrate plate;

FIG. 2 shows a section of the substrate plate having semiconductor lasers;

FIG. 3 shows a view of a lower side of the substrate plate;

FIG. 4 shows a perspective side view of a section of the substrate plate,

FIG. 5 shows a substrate having a semiconductor laser,

FIG. 6 shows an additional substrate having a semiconductor laser;

FIG. 7 shows the arrangement from FIG. 6 with a view of the second longitudinal side;

FIG. 8 shows a carrier having a substrate having a semiconductor laser;

FIG. 9 shows a carrier having a substrate having a semiconductor laser;

FIG. 10 shows an additional substrate having a semiconductor laser; and

FIG. 11 shows a schematic diagram of the lateral protrusion of the semiconductor with respect to the substrate.

### DETAILED DESCRIPTION OF ILLUSTRATIVE EMBODIMENTS

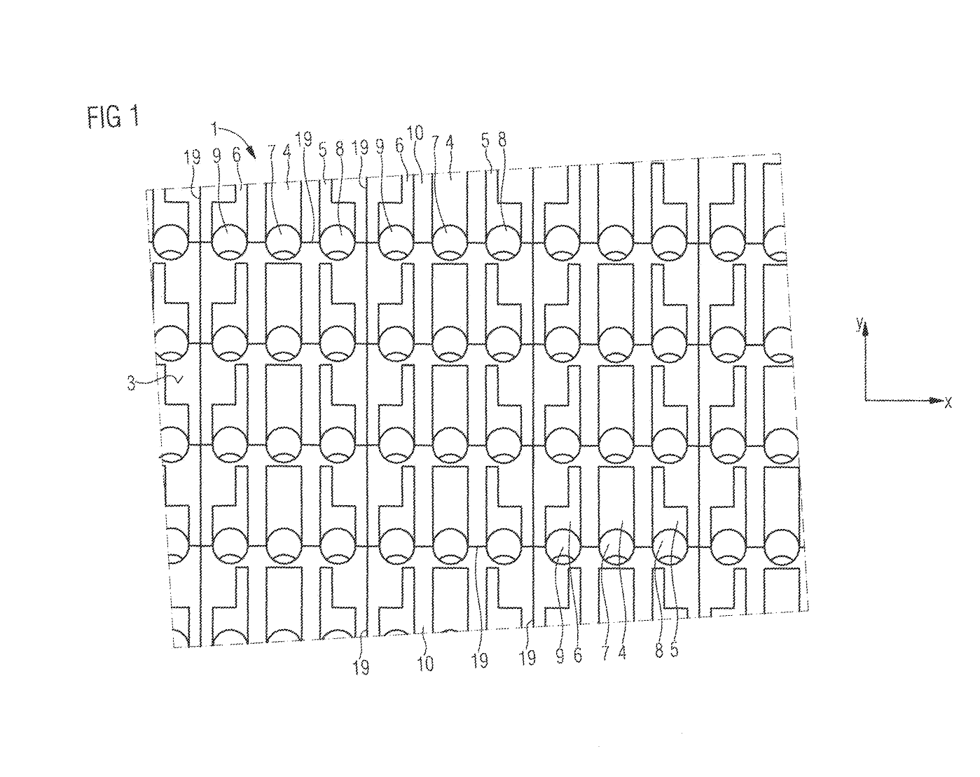

FIG. 1 shows a schematic representation of a section of a substrate plate 1 which is manufactured from an electrically insulating material. The substrate plate 1 may, for example, be made of aluminum nitrite, silicon, silicon carbide, or aluminum oxide. The substrate plate 1 has recesses 7, 8, 9. In the depicted exemplary embodiment, the recesses 7, 8, 9 are routed from an upper side 3 to a lower side of the substrate plate 1 and are configured in the form of continuous holes. Depending on the selected embodiment, the recesses 7, 8, 9 may also be introduced into the upper side 3 of the substrate plate 1 only to a defined depth, and not configured to the lower side of the substrate plate 1. Furthermore, the substrate plate 1 has a first contact pad 4, a second contact pad 5, and a third contact pad 6 on the upper side 3. Depending on the chosen embodiment, the contact pads 4, 5, 6 may be dispensed with, or the contact pads 4, 5, 6 may be configured in another form. The first contact pad 4 is configured as an elongate, rectangular area on the upper side 3 and is routed to a first recess 7. In addition, the first contact pad 4 in the depicted embodiment is also configured on an inner side of the first recess 7 and routed to the lower side of the substrate plate 1. Depending on the chosen embodiment, it may be sufficient if the first contact pad 4 extends into the first recess 7. In particular in the embodiment of the first recess 7 in the form of a blind hole, the first contact pad 4 is not routed to the lower side of the substrate plate 1.

In addition to the first contact pad 4, a second contact pad 5 is arranged on the upper side 3 of the substrate plate 1. In the depicted embodiment, the second contact pad 5 is configured as a stepped strip which is arranged parallel to the longitudinal direction of the first contact pad 4. The second contact pad 5 is routed via the broader strip section to a second recess 8, wherein the second contact pad 5 in the depicted embodiment is also configured on an inner wall of the second recess 8 and is routed to the lower side of the substrate plate 1. Depending on the chosen embodiment, it may be sufficient if the second contact pad 5 extends into the second recess 8, but is not routed to the lower side of the substrate plate 1. In particular in the embodiment of the second recess 8 in the form of a blind hole, the second contact pad 5 is not routed to the lower side of the substrate plate 1.

In addition, a third contact pad 6 is configured on the upper side 3 of substrate plate 1, opposite the second contact pad 5 with respect to the first contact pad 4. In the depicted exemplary embodiment, the third contact pad 6 is arranged and configured mirror-symmetrically to the second contact pad 5, with respect to the first contact pad 4. In addition, the third contact pad 6 extends to a third recess 9. In the depicted exemplary embodiment, the third contact pad 6 extends along an inner wall of the third recess 9 to a lower side of the substrate plate 1. Depending on the chosen embodiment, the third contact pad 6 and the third recess 9 may be dispensed with. A plurality of units 10 having a first, second, and third recess 7, 8, 9 and having a first, second, and third contact pad 4, 5, 6 is configured on the substrate plate 1. The units 10 are arranged in a defined grid, wherein in the depicted exemplary embodiment, the spacings between the recesses 7, 8, 9 are equally large in an x-direction and equally large in a y-direction. The x-direction and the y-direction are perpendicular to one another and are plotted in FIG. 1. In addition, the spacings of the recesses are greater in the y-direction than in the x-direction. Furthermore, the contact pads 4, 5, 6 extend parallel to the y-axis. The stepped configuration of the second and the third contact pads 5, 6 provides for conservation of contact material for the configuration of the contact pads 5, 6. Furthermore, later fracture edges 19 are depicted in the form of lines.

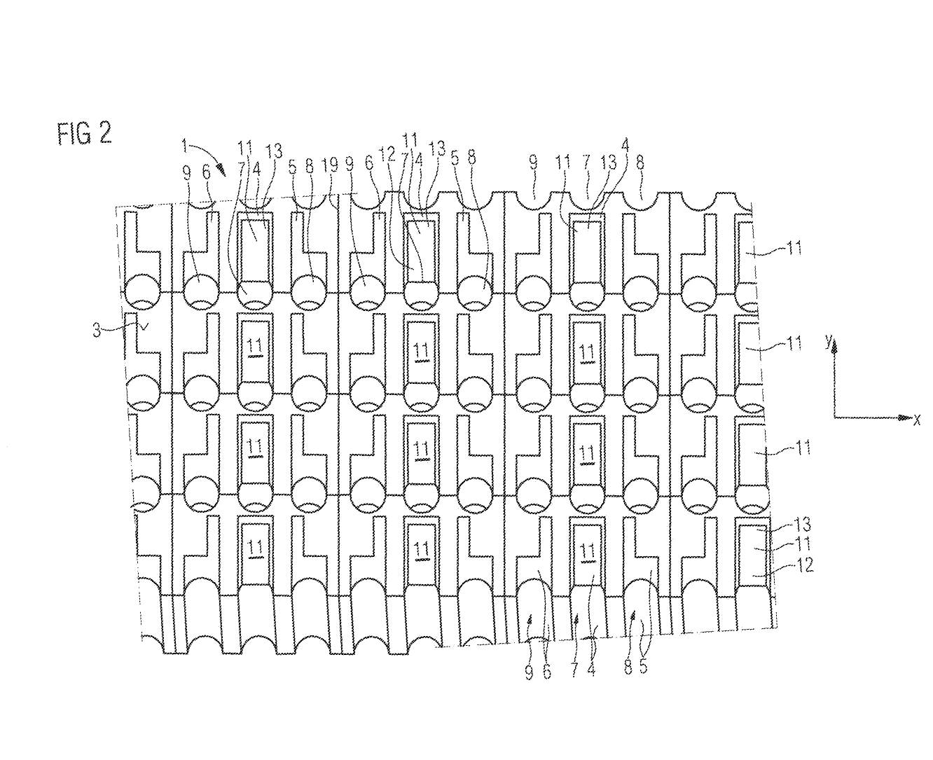

FIG. 2 shows the arrangement of FIG. 1, wherein a semiconductor laser 11 is applied to each of the first contact pads 4. The semiconductor lasers 11 are arranged having a first end 12 at least partially above a first recess 7. The first end 12 has the side face of the semiconductor laser 11, via which the electromagnetic radiation is emitted. A mirror is configured on the opposite, second end 13, which makes reflection of the laser radiation possible. Thus, the first end 12 of the semiconductor laser 11 protrudes over an edge region of the upper side 3 of the substrate plate 1, as is particularly clearly on the lower row of the semiconductor lasers 11 in FIG. 2. Depending on the chosen embodiment, the semiconductor lasers 11 may also be arranged in such a manner that the first end 12, via which the electromagnetic radiation is emitted by the semiconductor laser 11, is also arranged above a first recess 7 of an adjacent unit 10.

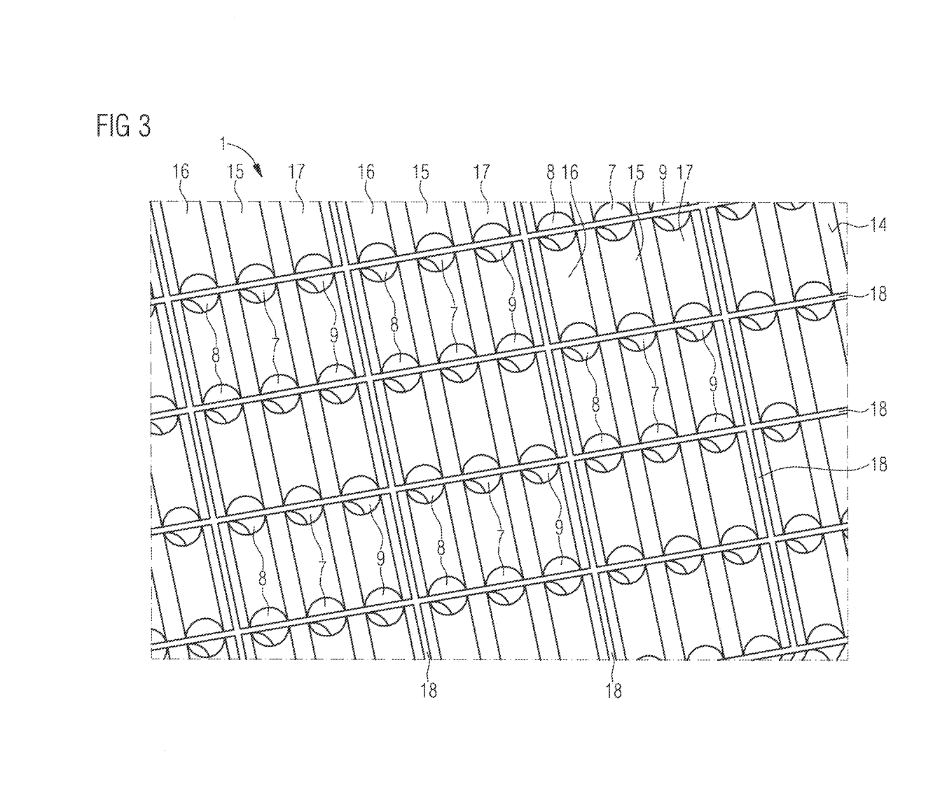

FIG. 3 shows a section of a lower side 14 of a substrate plate 1. Electrically conductive contact strips 15, 16, 17 are arranged here, wherein the first contact strip 15 is electrically conductively connected to a first contact pad 4 in each case via the first recesses 7. In particular, the contact strips 15 may be made of the same material as the first contact pads 4. The second contact strips 16 are electrically conductively in contact with the second contact pads 5 via second recesses 8.

The third contact strips 17 are electrically conductively in contact with the third contact pads 6 via the third recesses 9. In particular, the contact strips 15, 16, 17 are manufactured from the same material as the contact pads 4, 5, 6. For example, the contact pads 4, 5, 6 and the contact strips 15, 16, 17 may be applied on the upper side 3, in the recesses 7, 8, 9, or on the lower side 14 of the substrate plate 1, with the aid of a deposition process.

The semiconductor lasers 11 are, for example, mounted via a p-side to the substrate plate 1. The semiconductor lasers 11 have an active zone which is arranged close to the surface of the p-side of the semiconductor laser. Therefore, particularly in the case of p-down mounting, it is to be provided that the propagation of electromagnetic radiation emitted by the semiconductor laser 11 is not impaired by adjacent materials, for example, an upper side of the substrate plate 1 or a contact pad.

The advantage of the unimpaired emission of the electromagnetic radiation may also be achieved with the aid of the first recess 7, independently of the shape and the arrangement of the contact pads 4, 5, 6.

The contact pads 4, 5, 6 and the contact strips 15, 16, 17 are, for example, manufactured from a metal layer which is applied to, in particular is vapor-deposited onto, the upper side 3 of the substrate plate 1, the inner side of the recesses 7, 8, 9, and the lower side 14 of the substrate plate.

The semiconductor lasers 11 are, for example, attached on the upper side 3 of the substrate plate 1, in particular to the first contact pads 4, by means of gluing, silver-sintering, or via a eutectic gold/tin solder.

Breaking trenches 18 are introduced into the lower side 14 on the lower side 14 of the substrate plate 1. They may, for example, be produced with the aid of a scribing operation or with the aid of a laser beam. Depending on the chosen embodiment, it may be possible to dispense with the breaking trenches 18 if the substrate plate 1 is subdivided into individual substrates having at least one semiconductor laser 11, for example, with the aid of a sawing process.

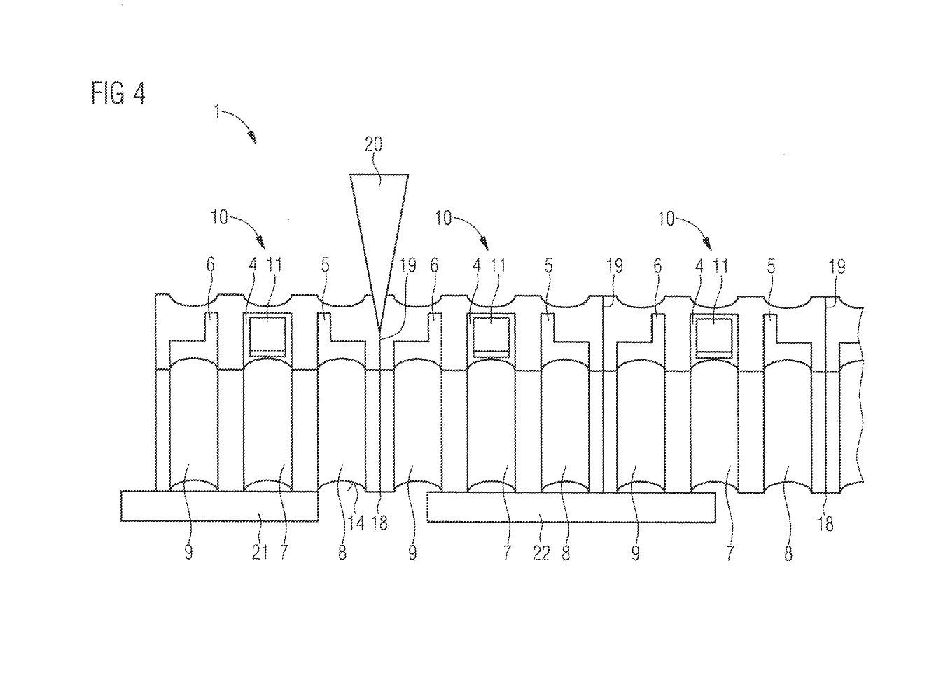

FIG. 4 shows a perspective view of a section of a substrate plate 1, which is configured in the form of an elongate bar having multiple units 10. The section has been manufactured, for example, by sawing or breaking the substrate plate 1. The units 10 are arranged in a row and are mechanically connected to one another. Desired fracture edges 19 are depicted as lines between the units 10. Breaking trenches 18 are configured on the lower side 14 of the substrate plate 1 along the desired fracture edges 19. For breaking the substrate plate 1, a breaking tool 20 is having a breaking edge is applied to the upper side 3 of the substrate plate 1, along the desired fracture edge 19. The breaking tool 20 is merely schematically depicted in the shape of a pointed triangle. Subsequently, the substrate plate 1 is pressed upward against the breaking tool 20 with the aid of two pressure plates 21, 22. The substrate plate 1 is thereby broken into the desired units 10. The section may also be manufactured from the substrate plate 1 in the same manner.

FIG. 5 shows a substrate 23 having a semiconductor laser 11 which was singulated from the substrate plate of FIGS. 2 to 4. It is apparent that a side face 24 of the semiconductor laser 11 via which the electromagnetic radiation is emitted by the semiconductor laser 11 is arranged above a first recess 7. Thus, the electromagnetic radiation may be emitted by the semiconductor laser 11 from the upper side of the substrate 23 with no interference. Depending on the selected embodiment, the lateral projection between the region of the side face 24 via which the electromagnetic radiation is emitted and the upper side 3 of the substrate 23 may lie, for example, in the range between 0.1 and 20 μM or more. In the embodiment depicted in FIG. 5, the side face 24 of the semiconductor laser 11 is arranged above the first recess 7, into which the first contact pad 4 is also routed. In addition, a first bonding wire 25 is provided, which electrically conductively connects a second electrical terminal 37 of the semiconductor laser 11 to the second contact pad 5. Furthermore, a second bonding wire 26 is provided, which electrically conductively connects the second electrical terminal 37 of the semiconductor laser 11 to the third contact pad 6. As already indicated above, the second bonding wire 26 may also be dispensed with. A first electrical terminal 36 of the semiconductor laser 11 is electrically contacted via the first contact pad 4 and an electrical contact correspondingly configured on the lower side of the semiconductor laser 11.

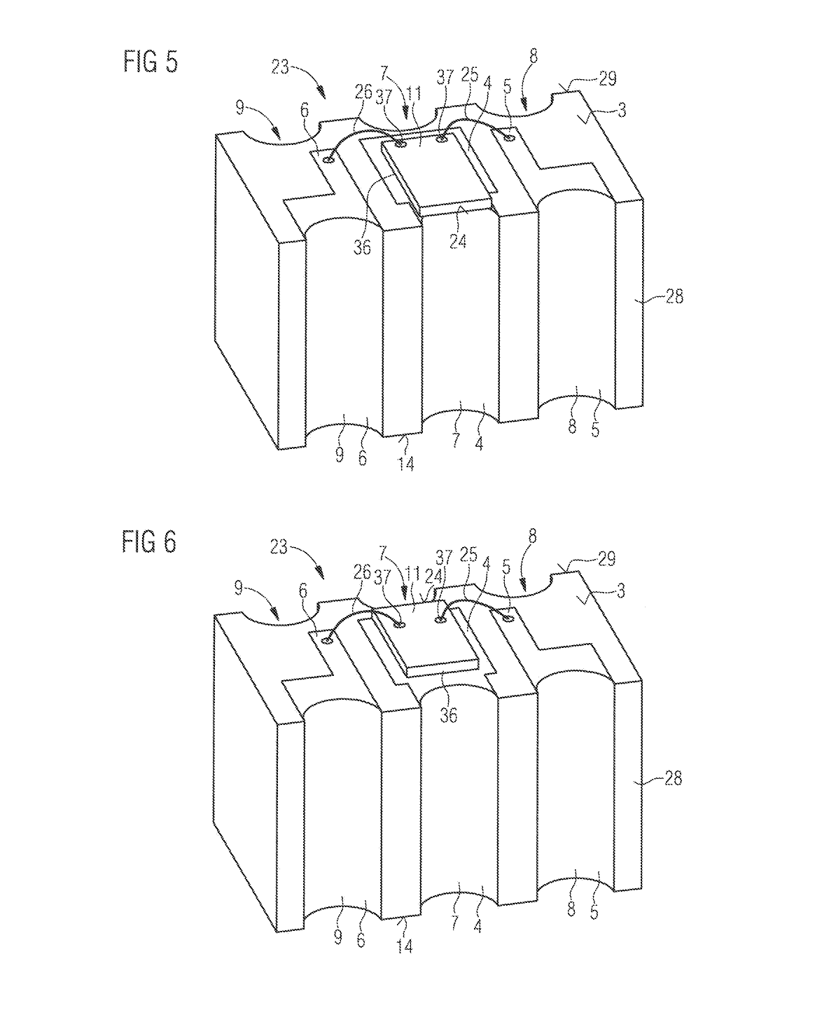

FIG. 6 shows an additional embodiment of a substrate 23 which is essentially configured according to the embodiment of FIG. 5, wherein, however, the side face 24 which emits the electromagnetic radiation of the semiconductor laser 11 is arranged opposite the embodiment of FIG. 5. In this embodiment, the side face 24 is arranged above an additional first recess 7, to which the first contact pad 4 is not routed. The additional first recess 7 is arranged opposite the first recess 7. The substrate 23 has two opposite longitudinal sides 28, 29, wherein three recesses 7, 8, 9 are introduced on each longitudinal side 28, 29. The three recesses 7, 8, 9 extend from the upper side 3 of the substrate 23 to the lower side 14 of the substrate 23. The recesses 7, 8, 9 are configured in the shape of half cylinders which are oriented perpendicularly to the upper side 3. In addition, the recesses 7, 8, 9 have the same shape. Furthermore, the spacing between the recesses of a longitudinal side 28, 29 is equally large. The recesses 7, 8, 9 of the two longitudinal sides 28, 29 are configured identically. The recesses 7, 8, 9 of the second longitudinal side 29 are also covered on the inner side by an electrically conductive contact pad 34. In addition, the contact pads 34 of the oppositely arranged recesses of the two longitudinal sides 28, 29 are interconnected via the contact strips 15, 16, 17 arranged on the lower side, as is apparent based on FIG. 3.

In the arrangement of FIG. 6, the first contact pad 4 is not routed to the first recess 7 of the second longitudinal side 29. Thus, the side face 24 of the semiconductor laser 11 may have a smaller projection to the inner side of the first recess 7, since the upper side 3 bordering on the first recess 7 of the second longitudinal side 29 is not covered by a contact pad. Thus, the risk of contamination of the side face 24 by material of the first contact pad 4 is reduced in this embodiment. The contamination may, for example, exist during the mounting of the semiconductor laser 11, i.e., during the mechanical and the electrical connection to the substrate 3 or to the first contact pad 4.

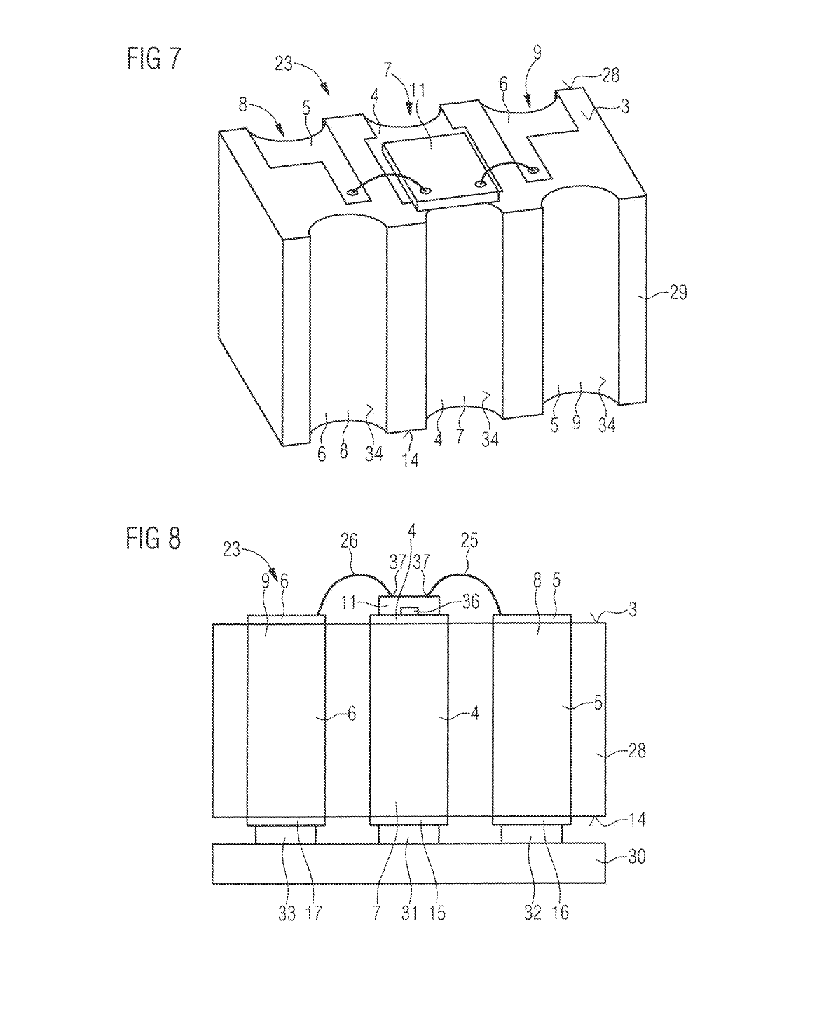

FIG. 7 shows the arrangement of FIG. 6 with a view of the second longitudinal side 29.

FIG. 8 shows an arrangement having a substrate 23 which is configured according to the embodiments of FIGS. 5 or 6 and is mounted on a carrier 3o via the lower side 14. FIG. 8 shows the substrate 23 with a view of the first longitudinal side 28. The carrier 30 has a first, second, and third additional electrical contact 31, 32, 33 on the upper side. The first, second, and third additional electrical contacts 31, 32, 33 may, for example, be configured in the form of a contact pad. The first contact strip 15 of the substrate 23, which is arranged on the lower side 14 and is electrically conductively connected to the first contact pad 4, rests on the first additional electrical contact 31 of the carrier 30. The second contact strip 16, which is configured on the lower side 14 of the substrate 23 and is conductively connected to the second contact pad 5, rests on the second additional electrical contact 32. The third contact strip 17, which is arranged on the lower side 14 of the substrate 23 and is conductively connected to the third contact pad 6, rests on the third additional electrical contact 33. Thus, an electrically conductive connection is configured between the first additional electrical contact 31 and the first contact pad 4, between the second electrical contact 32 and the second contact pad 5, and between the third additional electrical contact 33 and the third contact pad 6.

Depending on the chosen embodiment, the substrate 23 may be attached to the carrier 30 via a corresponding mechanical connection of the contact strips 15, 16, 17 to the additional electrical contacts 31, 32, 33. In addition, dependently or in addition, an additional connection layer, in particular an adhesive layer, may be configured between the lower side 14 of the substrate 23 and the upper side of the carrier 30, in order to attach the substrate 23 mechanically to the carrier 30.

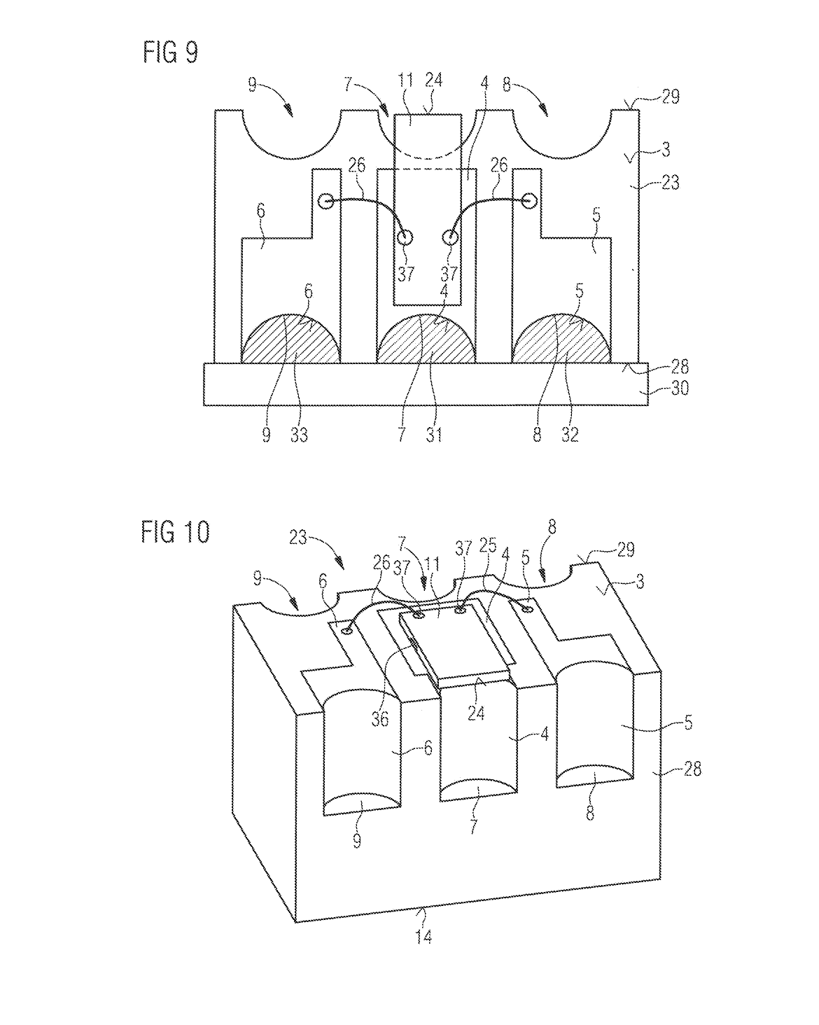

FIG. 9 shows an additional embodiment, in which a substrate 23 according to the embodiment of FIG. 6 is attached to an upper side of a carrier 3o via the first longitudinal side 28. In this case, the first additional electrical contact 31 of the carrier 3o is electrically conductively connected to the first contact pad 4 in the first recess 7. In addition, the second additional electrical contact 32 of the carrier 30 is electrically conductively connected to the second contact pad 5 in the region of the second recess 8. Furthermore, the third additional electrical contact 33 is electrically conductively connected to the third contact pad 6 of the third recess 9. In this embodiment, the side face 24 of the semiconductor laser 11 protrudes beyond the edge region of the first recess 7 which is configured on the second longitudinal side 29. Thus, the semiconductor laser 11 emits electromagnetic radiation opposite the carrier 30.

However, depending on the chosen embodiment, the semiconductor laser 11 may also be mounted in such a way that the side face 24 is arranged on the side of the carrier 30, wherein in this embodiment, however, the height of the semiconductor laser 11 must be offset with respect to the carrier 30, so that the electromagnetic radiation of the semiconductor laser 11 may be emitted over the carrier 30.

FIG. 10 shows one embodiment of a substrate 23 having a semiconductor laser, wherein the first, second, and third recesses 7, 8, 9 are also configured in the form of a recess, but are not routed to the lower side 14 of the substrate 23. In this embodiment as well, the described advantages may be utilized for mounting the semiconductor laser 11. In this case, the side face 24 of the semiconductor laser 11 which emits the electromagnetic radiation may protrude from the first longitudinal side 28 in the first recess 7 with respect to the substrate 23 into which the first contact pad 4 is routed, as depicted in FIG. 5. In addition, however, in this embodiment as well, the semiconductor laser 11 may protrude from the first recess 7 of the second longitudinal side 29, into which the first contact pad 4 of the semiconductor laser 11 is not routed, as depicted in FIG. 6.

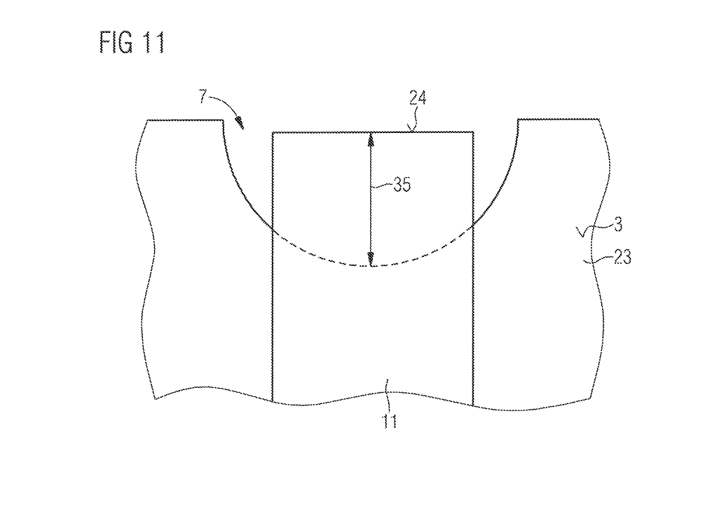

FIG. 11 shows a schematic diagram of the lateral spacing 35 which the side face 24 which emits the laser radiation has from the first recess 7.

The recesses 7, 8, 9 depicted in the figures have a cross section which is circular. Depending on the chosen embodiment, other cross sections, in particular the first recess, may also have a different cross section than the second recess, and the second recess may have a different cross section than the third recess.

In addition, a substrate 23 which is singulated from the substrate plate 1 may also have multiple semiconductor lasers 11 and correspondingly multiple first, second, third recesses 7, 8, 9 and corresponding first, second and third contact pads 4, 5, 6.

The p-side of the semiconductor laser 11 may face the substrate 23 or the substrate plate 1. As a result, the active zone, which is arranged closer to the p-side than to the n-side of the semiconductor laser 11, is arranged closer to the upper side 3 of the substrate plate 1 or to the upper side 3 of the substrate 23.

Instead of the semiconductor laser 11, which, for example, is configured in the form of laser diodes, light-emitting diodes may also be provided which emit the electromagnetic radiation on a side face 24.

Depending on the chosen embodiment, the configuration of the contact pads 4, 5, 6 in the first, second, and third recesses 7, 8, 9 may be dispensed with. It is in particular possible if the substrate 23 is mounted on the carrier 3o via the first longitudinal side 28.

Although the present invention has been illustrated and described in greater detail via the preferred exemplary embodiment, the present invention is not limited by the disclosed examples, and other variations may be derived from it by those skilled in the art without departing from the protective scope of the present invention.

1-15. (canceled)

16. An arrangement comprising:
a substrate having an upper side, side faces, and a lower side, wherein at least a first recess is provided at the upper side; and
a semiconductor laser arranged on the upper side of the substrate in such a way that a region of the side face of the semiconductor laser via which electromagnetic radiation is emitted is arranged above the first recess,
wherein a first contact pad is located on the upper side of the substrate, wherein the first contact pad extends from the upper side at least into the first recess and/or in a further first recess,
wherein a first electrical terminal of the semiconductor laser is connected to the first contact pad,
wherein at least a second recess is provided at the upper side of the substrate,
wherein the second recess borders on a side face of the substrate or is routed from the upper side of the substrate to the lower side of the substrate,
wherein a second contact pad is located on the upper side of the substrate,
wherein the second contact pad extends from the upper side at least into the second recess, and
wherein a second electrical terminal of the semiconductor laser is electrically conductively connected to the second contact pad.

17. The arrangement according to claim 16, wherein the first recess is bordering a side face of the substrate, and wherein the first recess is open laterally on the side face.

18. The arrangement according to claim 16, wherein the first recess extends from the upper side of the substrate to the lower side of the substrate, and wherein the first contact pad extends from the upper side of the substrate via the first recess to the lower side of the substrate.

19. The arrangement according to claim 16, wherein the second recess extends from the upper side of the substrate to the lower side of the substrate, and wherein the second contact pad extends from the upper side via the second recess to the lower side of the substrate.

20. The arrangement according to claim 16, further comprising at least a third recess at the upper side of the substrate, wherein the third recess borders a side face of the substrate or is routed from the upper side of the substrate to the lower side of the substrate, wherein a third contact pad is located on the upper side of the substrate, wherein the third contact pad extends at least into the third recess, and wherein the third contact pad is electrically conductively connected to the second electrical terminal of the semiconductor laser.

21. The arrangement according to claim 16, wherein the first recess is located at the side face of the substrate or is arranged on a carrier via the lower side, wherein the carrier has a first additional electrical contact, and wherein the first contact pad is connected to the first additional electrical contact of the carrier.

22. The arrangement according to claim 16, wherein the first recess is located at the side face of the substrate or is arranged on a carrier via the lower side, wherein the carrier has a first additional electrical contact, wherein the first contact pad is connected to the first additional electrical contact of the carrier, wherein the carrier has a second additional electrical contact, and wherein the second contact pad is connected to the second additional electrical contact of the carrier.

23. The arrangement according to claim 16, wherein the first recess is located at the side face of the substrate or is arranged on a carrier via the lower side, wherein the carrier has a first additional electrical contact, wherein the first contact pad is connected to the first additional electrical contact of the carrier, wherein the carrier has a third additional electrical contact, and wherein a third contact pad is connected to the third additional electrical contact of the carrier.

24. The arrangement according to claim 16, wherein the first recess is configured on the side face of the substrate or is arranged on a carrier via the lower side, wherein the carrier has a first additional electrical contact, and wherein the first contact pad is connected to the first additional electrical contact of the carrier, wherein the carrier has a second additional electrical contact, wherein the second contact pad is connected to the second additional electrical contact of the carrier, and wherein the carrier has a third additional electrical contact, and wherein the third contact pad is connected to the third additional electrical contact of the carrier.

25. The arrangement according to claim 20, wherein the first, the second, and/or the third recesses are provided in form of a hole or in form of a hole which is open laterally in a longitudinal direction.

26. A method for manufacturing an arrangement having a substrate and a semiconductor laser, the method comprising:
providing a substrate plate having multiple recesses;
mounting multiple semiconductor lasers on the substrate plate so that the semiconductor lasers are respectively arranged above a first recess at a region of a side face via which electromagnetic radiation is emitted; and
singulating the substrate plate into substrates each having at least one semiconductor laser.

27. The method according to claim 26, further comprising applying multiple first contact pads which are separate from one another to an upper side of the substrate plate so that the first contact pads extend from the upper side of the substrate plate to an associated first recess, and wherein first electrical terminals of the semiconductor lasers are connected to the first contact pads so that the semiconductor lasers are placed on the first contact pads.

28. The method according to one of claim 26, further comprising arranging the substrate on a carrier via a side face on which the first recess borders, or via a lower side, wherein the carrier has a first additional electrical contact, and wherein a first contact pad of the substrate is electrically conductively connected to the first additional electrical contact of the carrier.

29. The method according to any one of claim 26, wherein singulating the substrate plate comprises introducing fracture sizes on a lower side of the substrate plate via a laser and breaking the substrate plate into substrates along fracture trenches.
